(19) United States
(12) Patent Application Publication
(10) Pub. No.: US 2012/0120623 A1
(43) Pub. Date: May 17, 2012

(54) LEAD PIN FOR PACKAGE SUBSTRATE AND PACKAGE SUBSTRATE USING THE SAME

(75) Inventors: Yong Ho BAEK, Gyeongsangnam-do (KR); Seok Hyun PARK, Gyeongsangnam-do (KR); Ki Taek LEE, Seoul (KR)

(73) Assignee: SAMSUNG ELECTRO-MECHANICS CO., LTD., Gyunggi-do (KR)

(21) Appl. No.: 13/007,554

(22) Filed: Jan. 14, 2011

(30) Foreign Application Priority Data
Nov. 17, 2010 (KR) 10-2010-0114628

(51) Int. Cl. H05K 7/12; H01R 13/02

(52) U.S. Cl. 361/767; 439/884

(57) ABSTRACT

Disclosed herein are a lead pin for a package substrate and a package substrate using the same. The lead pin for a package substrate, includes: a connection pin having a first through hole; and a pin head part provided with a groove including a second through hole formed therein and having a first head formed at one end part of the connection pin in a trapezoidal column shape, wherein the first through hole and the groove are connected to each other through the second through hole through which the upper portion and the lower portion the lead pin penetrate each other, whereby voids generated at the time of reflow can be discharged to the outside through the through hole formed in the lead pin, thereby making it possible to reduce a defect rate generated during a process of manufacturing a package substrate.

### CROSS REFERENCE TO RELATED APPLICATION

This application claims the benefit of Korean Patent Application No. 10-2010-0114628, filed on Nov. 17, 2010, entitled “Lead Pin For Package Substrate And Package Substrate Using The Same” which is hereby incorporated by reference in its entirety into this application.

### BACKGROUND OF THE INVENTION

1. Technical Field

The present invention relates to a lead pin for a package substrate and a package substrate using the same.

2. Description of the Related Art

In a PGA substrate, when a T-type lead pin is bonded to a pad on a package substrate by using an Sn95—Sb5 solder (melting point of 232 to 240) having a melting point higher than that of an Sn96—Ag3.5—X based solder (melting point 221) used when bonding IC chips.

The above-mentioned process is essential to prevent the pin from being separated when the IC chips are mounted on the package substrate. Generally, in order to minimize thermal impact applied to the package substrate, the above-mentioned process shortens the time when a soldering is maintained at a temperature of a melting point or more, such that the time of discharging bubbles in the soldering is insufficient. In this case, the soldering are in a non-uniform distribution state to cause a problem of biasing the lead pin due to a tension with the lead pin, thereby making it possible to degrade the pin pull strength.

Further, even though the above-mentioned bubbles do not cause any problems during the bonding of the lead pin, the IC chips are again heated during the mounting process of the IC chips, such that they can cause the defects of the pin.

### SUMMARY OF THE INVENTION

The present invention has been made in an effort to provide a lead pin for a package substrate and a package substrate using the same capable of discharging voids generated at the time of reflow to the outside by forming a through hole in the lead pin.

Further, the present invention has been made in an effort to provide a pin pull strength of a lead pin by increasing a contacting area between a head of the lead pin and a solder.

In addition, the present invention has been made in an effort to prevent a phenomenon of covering an upper portion of a lead pin with a solder when the lead pin contacts a substrate pad.

Moreover, the present invention has been made in an effort to uniformly manage a solder volume and align pins by forming a solder to be filled in a groove formed in an inner side of a lead pin.

According to a preferred embodiment of the present invention, there is provided a lead pin for a package substrate, including: a connection pin having a first through hole; and a pin head part provided with a groove including a second through hole formed therein and having a first head formed at one end part of the connection pin in a trapezoidal column shape, wherein the first through hole and the groove are connected to each other through the second through hole through so that the upper portion and the lower portion of the lead pin penetrate through each other.

The pin head part may further include a second head in a plate shape formed at one end portion of the connection pin to be disposed between the connection pin and the first head and having a central hole through which the upper and lower portions penetrate at a central area contacting the first through hole.

The second head may be any one of a polygonal shape and a circular shape and a combination thereof.

The groove may be formed in a shape in which the diameter of the groove is gradually large based on a surface contacting at one end portion of the connection pin.

The groove may be a semispherical shape.

The connection pin may be any one of a polygonal column and a cylinder and a combination thereof.

The trapezoidal column shape of the first head may be a circular shape or an angled shape.

The roughness may be formed at the outer peripheral surface of the pin head part of the lead pin, the inner side surface of the groove, or the outer peripheral surface of the pin head part and the inner side surface of the groove of the pin head part.

According to another preferred embodiment of the present invention, there is provided a package substrate, including: a base substrate having a connection pad exposed through an opening of a solder resist layer; a lead pin including a connection pin and a pin head part provided with a groove including a second through hole connected to a first through hole formed therein and having a first head formed at one end portion of the connection pin in a trapezoidal column shape; and a solder bonding a pin head part of the lead pin to a connection pad of the base substrate.

The solder may be filled in the groove of the first head and is formed to contact the outer peripheral surface of the pin head part.

The solder may be formed in a shape in which it is filled in the groove of the first head.

The pin head part may further include a second head in a plate shape formed at one end portion of the connection pin to be disposed between the connection pin and the first head and having a central hole through which the upper and lower portions penetrate at the central area contacting the first through hole.

The second head may be any one of a polygonal shape and a circular shape and a combination thereof.

The groove may be formed in a shape in which the diameter of the groove is gradually large based on a surface contacting at one end portion of the connection pin.

The groove may be a semispherical shape.

The connection pin may be any one of a polygonal column and a cylinder and a combination thereof.

The trapezoidal column shape of the first head may be a circular shape or an angled shape.

Roughness may be formed at the outer peripheral surface of the pin head part of the lead pin, the inner side surface of the groove, or the outer peripheral surface of the pin head part and the inner side surface of the groove of the pin head part.

### BRIEF DESCRIPTION OF THE DRAWINGS

FIG. 1 is a front view showing a structure of a lead pin for a package substrate according to the present invention;

FIG. 2 is a perspective view showing the structure of the lead pin for a package substrate according to the present invention;

FIG. 3 is a plan view of a first head according to the present invention;

FIG. 4 is a bottom view of the first head according to the present invention;

FIG. 5 is a diagram showing an exemplary embodiment of a package substrate bonded to the lead pin according to the present invention; and

FIG. 6 is a diagram showing another example of a package substrate bonded to a lead pin according to the present invention.

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted.

Hereinafter, preferred embodiments of the present invention will be described in detail with reference to the accompanying drawings.

### Lead Pin for Package Substrate

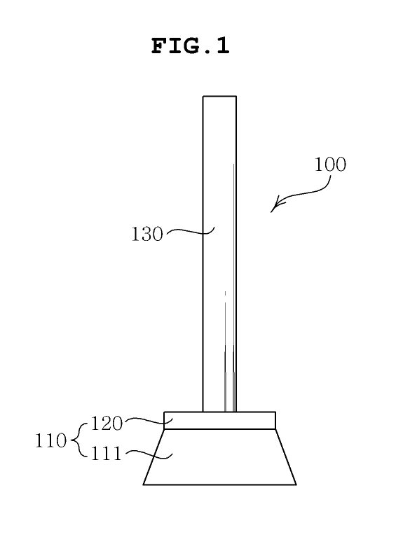

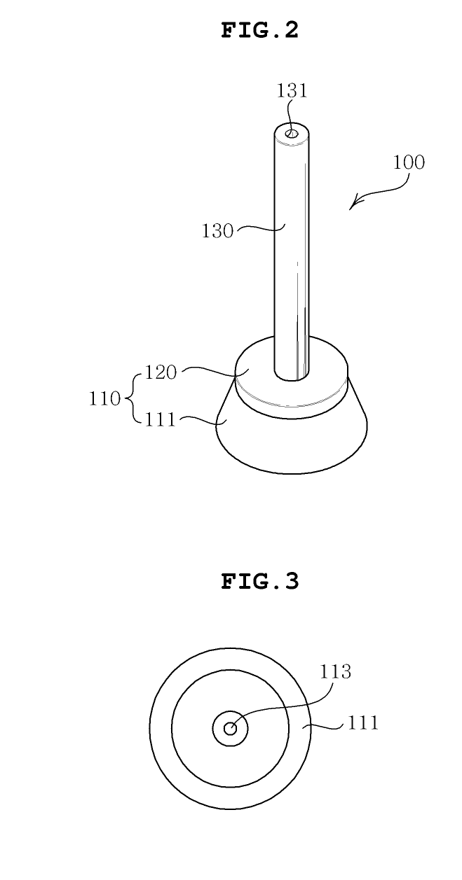

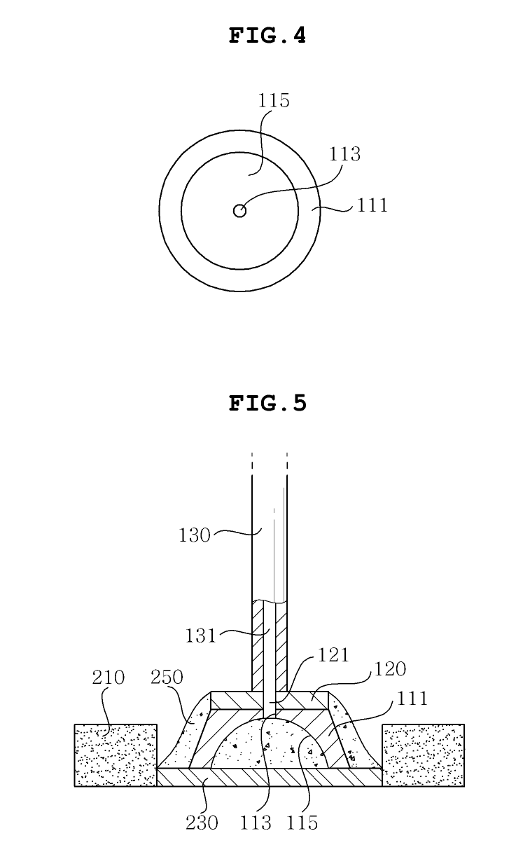

FIG. 1 is a front view showing a structure of a lead pin for a package substrate according to the present invention, FIG. 2 is a perspective view showing the structure of the lead pin for a package substrate according to the present invention, FIG. 3 is a plan view of a first head according to the present invention, and FIG. 4 is a bottom view of the first head according to the present invention.

As shown, a lead pin 100 may be configured to include a pin head part 110 and a connection pin 130 vertically disposed on the pin head part 110.

Described in more detail, the connection pin 130 may be formed to have a through hole 131.

For example, the connection pin 130 is formed in a cylinder as shown in FIG. 1 and has a first through hole 131 through which the upper portion and the lower portion of the connection pin 130 penetrate as shown in FIG. 2.

In this configuration, the shape of the connection pin 130 is not limited to the above-mentioned cylinder and may be any one of a polygonal column (for example, a polygonal column such as a triangular column and a quadrangular column) and a cylinder and a combination thereof.

As shown in FIGS. 3 and 4, the pin head part 110 is provided with a groove 115 including a second through hole 113 therein and may include a first head 111 in a trapezoidal column shape formed at one end portion of the connection pin 130.

In this configuration, the first through hole 131 and the groove 115 formed in the lead pin 100 are connected to each other through the second through hole 113, such that the upper portion and the lower portion of the lead pin 100 penetrate through each other.

As described above, since the upper portion and the lower portion of the lead pin 100 penetrate through each other, the voids generated at the time of reflow may be discharged to the outside along a path formed through the first through hole 131 and the groove 115, such that the problems caused due to the voids generated during the process of bonding the lead pin in the processes of manufacturing the package substrate can be solved.

In addition, the groove 115 may be formed in a shape in which the diameter of the groove 115 is gradually increased based on a surface contacting one end portion of the connection pin 130. For example, as shown in FIG. 4 that is a bottom view of the first head 111, the shape of the groove may be a semispherical shape, but is not limited thereto.

As described above, as the groove 115 is formed in the pin head part 110, the contacting area (the outer peripheral surface of the pin head part 110 and the inner side surface of the groove 115) with the solder is wide when the lead pin 100 is mounted on the package substrate, such that the pin pull strength between the lead pin 100 and the solder (or package substrate) can be improved.

In addition, the trapezoidal column shape of the first head 111 may be a circular shape or an angled shape.

In this configuration, the upper and lower cross section of the first head 111 may be a circular shape or a polygonal shape. When the trapezoidal column shape of the first head is a circular shape, the upper and lower cross section is a circular shape and when the trapezoidal column shape of the first head is an angled shape, the upper and lower cross section is a polygonal shape.

Meanwhile, the pin head part 110 may further include a second head 120 disposed between the first head 111 and the connection pin 130.

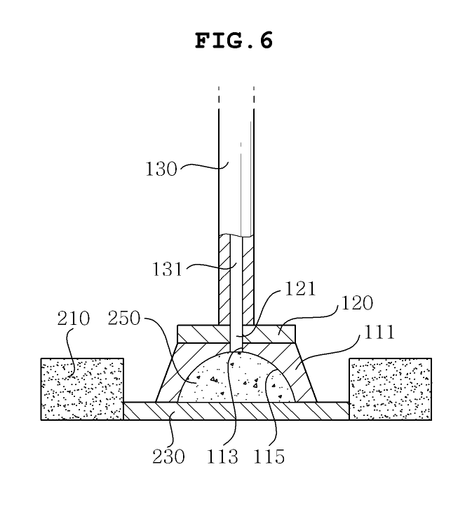

The second head 120 is formed at one end portion of the connection pin 130 to be disposed between the connection pin 130 and the first head 111 and may be formed in a plate shape having a central hole 121 (FIGS. 5 and 6) through which the upper and lower portions penetrate at a central area contacting the first through hole 131.

In this configuration, the central hole 121 formed in the second head 120 is connected to the first through hole 131 of the connection pin 130 and the second through hole 113 of the first head 111 so that the upper and lower portions of the lead pin penetrate through each other, such that the voids generated during the manufacturing of the package substrate can be discharged to the outside even though the second head 120 is further provided.

As shown in FIGS. 1 and 2, the diameter of the contacting surface between the first head 111 and the second head 120 is equal to the diameter of the second head, but the diameter of the first head 111 is gradually large based on the contacting surface with the second head.

In addition, the second head 120 may be any one of a polygonal shape (for example, a polygonal shape such as a triangular shape and a quadrangular shape) and a circular shape and a combination thereof.

Further, roughness may be formed at the outer peripheral surface of the pin head part 110 of the lead pin 100, the inner side surface of the groove 115, or the outer peripheral surface of the pin head part 110 and the inner side surface of the groove 115 of the lead pin 100 as shown in FIGS. 1 to 4, which can improve the pin pull strength between the lead pin 100 and the solder to be described below. That is, the roughness may be formed on the surface of the pin head part (the outer peripheral surface of the pin head part 110 and the inner side surface of the groove 115).

The groove 115 (for example, a semispherical shape, etc.) of the pin head part shown in FIGS. 1 to 4 and the through holes (the first through hole 131, the central hole 121, the second through hole 113) may be manufactured by changing the casting shape and the shape of the blanking molding when manufacturing the wire during the process of manufacturing the pins.

### Package Substrate Bonded to Lead Pin

The present drawings schematically show the printed circuit board, while omitting other detailed components of the semiconductor package substrate other than feature components according to the preferred embodiments. It can be appreciated by those skilled in the art that the lead pin of the present invention may be applied to all the semiconductor package structure known to those skilled in the art without being specifically limited.

FIGS. 5 and 6 are diagrams showing an embodiment of a package substrate bonded to a lead pin according to the present invention.

As shown, the package substrate bonded to the lead pin may include the base substrate, the lead pin 100, and a solder 250.

Described in more detail, the base substrate may have a connection pad 230 exposed through an opening of the solder resist layer 210.

The base substrate may preferably be a printed circuit board as a circuit board in which a circuit of one or more layer including the connection pad 230 is formed on the insulating layer. Even though the present drawings describe that the detailed inner circuit configuration is omitted for convenience of explanation, it can be apparently appreciated from those skilled in the art that a general circuit board formed with a circuit of one or more layer may be applied to the insulating layer as the base substrate.

As the insulating layer, a resin insulating layer may be used. As the resin insulating layer, a thermosetting resin such as an epoxy resin, a thermoplastic resin such as polyimide, or a resin, in which a reinforcement material such as a glass fiber or an inorganic filler is impregnated, such as prepreg may be used. Further, as the resin insulating layer, the thermosetting resin and/or the photocurable resin, or the like, may be used; however, the preferred embodiment is not specifically limited thereto.

A material for a circuit including the connection pad 230 may be used without limitation if a conductive metal for a circuit may be used in the field of the circuit board. Generally, copper is used for the printed circuit board.

The solder resist layer 210 serves as a protective layer protecting an outermost circuit and is formed for electrical insulation and is provided with an opening to expose the connection pad 230 at the outermost layer. As known in those skilled in the art, the solder resist layer 210 may be configured of, for example, solder resist ink, a solder resist film, or an encapsulant, or the like, but is not limited thereto.

The exposed connection pad 230 may be further provided with a surface treatment layer (not shown), if necessary.

The surface treatment layer is not specifically limited thereto if it is known to those skilled in the art. For example, the surface treatment layer may be formed by electro gold plating, immersion gold plating, organic solderability preservative (OSP), immersion tin plating, immersion silver plating, electroless nickel and immersion gold (ENIG), direct immersion gold (DIG) plating, hot air solder leveling (HASL), or the like.

The inner side of the lead pin 100 is provided with the connection pin 130 having the first through hole 131 and the groove 115 including the second through hole 113 connected with the first through hole 131 and may include the pin head part 110 having the first head 111 formed at one end portion of the connection pin 130 in the trapezoidal column form.

In this configuration, the trapezoidal column shape of the first head 111 may be a circular shape or an angled shape.

For example, the outer peripheral surface of the first head 111 may be a circular shape without an angle as shown in FIGS. 1 and 2. Although not shown, the outer peripheral surface of the first head 111 may be a shape having a plurality of angle.

Meanwhile, the pin head part 110 is formed at one end portion of the connection pin 130 to be disposed between the connection pin 130 and the first head 111 and may further include the second head 120 in a plate shape having the central hole 121 through which the upper and lower portions penetrate at the central area contacting the first through hole 131.

The structure in that the second head 120 is included in the pin head part 110 has a form that the first head 111, the second head 120, and the connection pin 130 are sequentially arranged based on the surface of the connection pad 230, as shown in FIG. 5.

In this configuration, the second head 120 may be any one of a polygonal shape (for example, a polygonal shape such as a triangular shape and a quadrangular shape) and a circular shape and a combination thereof.

Further, the groove 115 may be formed in a shape in which the diameter of the groove is gradually large based on the surface contacting one end portion of the connection pin 130, for example, in a semispherical shape, but is not limited thereto.

Further, the connection pin 130 may be any one of a polygonal column (for example, a polygonal column such as a triangular column and a quadrangular column) and a cylinder and a combination thereof.

The solder 250 may be formed in a shape in which the pin head part 110 of the lead pins 100 is bonded to the connection pad 230 of the base substrate.

In this configuration, the material of the solder 250 is not specifically limited and therefore, may be made of a typical component known to those skilled in the art.

As shown in FIG. 5, the solder 250 may be formed to be filled in the groove 115 of the first head 111 and to contact the outer peripheral surface of the pin head part 110.

For example, the solder 250 is formed in a shape in which it surrounds the outer peripheral surface of the pin head part 110 and fills the groove 115.

In this configuration, the process of mounting the lead pin 100 on the connection pad 230 puts the solder on the connection pad 230 and mounts the lead pin 100, thereby forming the solder on the groove 115 and the outer peripheral surface of the pin head part 110.

In this case, the pin head part 110 is configured to include the first head 111 in a trapezoidal column shape and a second head 120 in a plate shape, which can prevent a climb phenomenon where the solder paste climbs along the surface of the connection pin 130 during the process of mounting the lead pin 100 on the connection pad 230.

Further, as shown in FIG. 6, the solder 250 may be formed in a shape in which it is filled in the groove 115 of the first head 111.

In this configuration, when the lead pin 100 is mounted on the connection pad 230, the process of putting the solder on the connection pad 230 may be omitted since the lead pin 100 is disposed on the connection pad 230 after the solder is first filled in the groove 115 of the pin head part 110. As a result, the present invention can implement the uniform solder volume management and the excellent pin alignment.

In addition, the solder 250 is formed to be filled in the groove 115, which can also prevent the climb phenomenon in which the solder paste climbs along the surface of the connection pin 130 on the pin head part 110 during the process.

Further, the roughness is formed in the outer peripheral surface of the pin head part 110 of the lead pin 100, the inner side surface of the groove 115, or the outer peripheral surface of the pin head part 110 of the lead pin 100 and the inner side surface of the groove 115, the pin pull strength between the solder 250 and the lead pin 100 can be improved.

As set forth above, the lead pin for a package substrate and the package substrate using the same according to the present invention discharge voids generated at the time of reflow to the outside by forming the through hole in the lead pin, thereby making it possible to reduce the defect rate generated during the process of manufacturing the package substrate.

Further, the present invention forms the groove in the head of the lead pin and forms the solder at the outer peripheral surface of the groove and the head of the lead pin to increase the contacting area between the lead pin and the solder, thereby making it possible to improve the pin pull strength of the lead pin.

In addition, the present invention prevents a phenomenon of covering the upper portion of the lead pin with a solder when the lead pin contacts the substrate pad.

Moreover, the present invention fills the groove formed in the lead pin with the solder, thereby making it possible to uniformly manage the solder volume and align the pins.

Although the preferred embodiments of the present invention have been disclosed for illustrative purposes, they are for specifically explaining the present invention and thus a lead pin for a package substrate and a package substrate using the same according to the present invention are not limited thereto, but those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A lead pin for a package substrate, comprising:
a connection pin having a first through hole; and
a pin head part provided with a groove including a second through hole formed therein and having a first head formed at one end part of the connection pin in a trapezoidal column shape,
wherein the first through hole and the groove are connected to each other through the second through hole through so that the upper portion and the lower portion of the lead pin penetrate through each other.

2. The lead pin for a package substrate as set forth in claim 1, wherein the pin head part further includes a second head in a plate shape formed at one end portion of the connection pin to be disposed between the connection pin and the first head and having a central hole through which the upper and lower portions penetrate at a central area contacting the first through hole.

3. The lead pin for a package substrate as set forth in claim 2, wherein the second head is any one of a polygonal shape and a circular shape and a combination thereof.

4. The lead pin for a package substrate as set forth in claim 1, wherein the groove is formed in a shape in which the diameter of the groove is gradually large based on a surface contacting at one end portion of the connection pin.

5. The lead pin for a package substrate as set forth in claim 4, wherein the groove is a semispherical shape.

6. The lead pin for a package substrate as set forth in claim 1, wherein the connection pin is any one of a polygonal column and a cylinder and a combination thereof.

7. The lead pin for a package substrate as set forth in claim 1, wherein the trapezoidal column shape of the first head is a circular shape or an angled shape.

8. The lead pin for a package substrate as set forth in claim 1, wherein roughness is formed at the outer peripheral surface of the pin head part of the lead pin, the inner side surface of the groove, or the outer peripheral surface of the pin head part and the inner side surface of the groove of the pin head part.

9. A package substrate, comprising:
a base substrate having a connection pad exposed through an opening of a solder resist layer;
a lead pin including a connection pin and a pin head part provided with a groove including a second through hole connected to a first through hole formed therein and having a first head formed at one end portion of the connection pin in a trapezoidal column shape; and
a solder bonding a pin head part of the lead pin to a connection pad of the base substrate.

10. The package substrate as set forth in claim 9, wherein the solder is filled in the groove of the first head and is formed to contact the outer peripheral surface of the pin head part.

11. The package substrate as set forth in claim 9, wherein the solder is formed in a shape in which it is filled in the groove of the first head.

12. The package substrate as set forth in claim 9, wherein the pin head part further includes a second head in a plate shape formed at one end portion of the connection pin to be disposed between the connection pin and the first head and having a central hole through which the upper and lower portions penetrate at the central area contacting the first through hole.

13. The package substrate as set forth in claim 12, wherein the second head is any one of a polygonal shape and a circular shape and a combination thereof.

14. The package substrate as set forth in claim 9, wherein the groove is formed in a shape in which the diameter of the groove is gradually large based on a surface contacting at one end portion of the connection pin.

15. The package substrate as set forth in claim 14, wherein the groove is a semispherical shape.

16. The package substrate as set forth in claim 9, wherein the connection pin is any one of a polygonal column and a cylinder and a combination thereof.

17. The package substrate as set forth in claim 9, wherein the trapezoidal column shape of the first head is a circular shape or an angled shape.

18. The package substrate as set forth in claim 9, wherein roughness is formed at the outer peripheral surface of the pin head part of the lead pin, the inner side surface of the groove, or the outer peripheral surface of the pin head part and the inner side surface of the groove of the pin head part.
